(19) United States
(12) Patent Application Publication
(10) Pub. No.: US 2026/0058229 A1
(43) Pub. Date: Feb. 26, 2026

(54) ELECTRICAL ENERGY STORAGE MODULE HAVING INTEGRATED POWER CONVERSION MEANS, AND ELECTRICAL ENERGY STORE INCORPORATING SAME

(71) Applicants: STELLANTIS AUTO SAS, Poissy (FR); CENTRALE SUPELEC, Gif-sur Yvette (FR); CENTRE NATIONAL DE LA RECHERCHE SCIENTIFIQUE, Paris cedex 16 (FR); CONSERVATOIRE NATIONAL DES ARTS ET METIERS, Paris cedex 03 (FR); CY CERGY PARIS UNIVERSITE, Cergy (FR); SAFT, Levallois Perret (FR); SORBONNE UNIVERSITE, Paris (FR); UNIVERSITE PARIS-SACLAY, Gif-Sur-Yvette (FR); ÉCOLE NORMALE SUPÈRIEURE PARIS-SACLAY, Gif-sur-Yvette (FR)

(72) Inventors: Francis Roy, Les Ulis (FR); Marc Boulay, Marly Le Roi (FR); Thomas Peuchant, Le Bouscat (FR); Alexandre Narbonne, Blanquefort (FR); David Herpe, Tresses (FR); Denis Labrousse, Poitiers (FR); Eric Laboure, Cachan (FR)

(21) Appl. No.: 19/106,968

(22) PCT Filed: Aug. 30, 2023
(86) PCT No.: PCT/FR2023/051312

§ 371 Date: Feb. 26, 2025

(30) Foreign Application Priority Data
Sep. 5, 2022 (FR) FR2208861

(51) Int. Cl. H01M 10/42; H01M 50/249; H01M 50/251; H01M 50/284; H01M 50/51; H02J 7/00; H05K 7/20

(52) U.S. Cl. CPC H01M 10/4257; H01M 50/249; H01M 50/284; H01M 50/51; H02J 7/0063; H05K 7/20927; H01M 50/251; H02J 2207/20; H02J 2310/48

(57) ABSTRACT

The electrical energy storage module (M1-In) comprises a plurality of elementary storage cells (C1 to C12). According to the invention, the module comprises at least one cell unit (U1-1,U1-2) including a plurality of elementary storage cells connected in series (C1 to C6; C7 to C12) and integrated power-switching means (P1, S1; P2, S2) dedicated to this cell unit, delivering, between two power output terminals (B1, B2) of the cell unit, a positive DC voltage, a negative DC voltage, a zero voltage or a high impedance state, depending on a command received by the cell unit.

### CROSS-REFERENCE TO RELATED APPLICATIONS

This application is the US National Stage under 35 USC § 371 of International Application No. PCT/FR2023/051312, filed Aug. 30, 2023, which claims priority to French App. No. 2208861 filed on Sep. 5, 2022, the content (text, drawings and claims) of both said applications being incorporated by reference herein.

### BACKGROUND

This application generally relates to the storage of electrical energy and electrical power conversion, particularly in mobile applications, such as vehicles, equipped with an electrified powertrain or stationary energy storage and conversion applications.

More particularly, an electrical energy storage module is disclosed having integrated power conversion means. Also disclosed is an electrical energy storage unit formed by the association of several electrical energy storage modules and suitable for direct connection to different types of electrical networks present in an electrified vehicle, such as a hybrid or all-electric vehicle, or in an electrical microgrid comprising the production, storage and distribution of electrical energy.

Generally speaking, in an electrical energy storage unit, for example of the Lithium-Ion type, so-called “Li-ion”, a plurality of elementary energy storage cells are interconnected in series to obtain a desired nominal voltage. To achieve the required level of capacity, cells can also be doubled, tripled or more, by placing them in parallel.

For example, automobile manufacturers have chosen to group Li-ion cells into modules with electrical couplings known as “1p12s” and “2p6s”, corresponding respectively to twelve cells in series and six packs in series of two cells in parallel per pack. The electrical energy storage unit obtained with the above-mentioned arrangement delivers a direct current to the vehicle's on-board power network, typically 450V or even 800V. Electronic power conversion means are provided to convert direct current into alternating current, to lower the voltage or otherwise, according to the needs of other vehicle on-board networks or actuators to be powered.

In stationary applications, Li-ion cells are electrically coupled within a module. Several modules are assembled in series to deliver a DC voltage of up to 1500V. Power conversion means deliver an AC voltage to exchange energy with the distribution network, via an intermediate voltage transformer if necessary.

The electric energy storage architecture described above is the one currently used for electric mobility and stationary applications. In particular, it has the following disadvantages:

1) A high voltage is present inside the electrical energy storage unit. Dismantling/opening the storage unit requires specific skills and the use of individual and collective safety equipment, which means that, in the field of consumer mobility, these operations cannot be carried out in a large number of car garages.

2) The electrical energy storage unit operates on direct current, which implies the need for electronic power conversion means to adapt voltage and current to the needs of electrical consumer devices (i.e., actuators, electric vehicle on-board networks, auxiliary functions of a stationary battery).

3) The Li-ion cells in the electrical energy storage unit are subjected to the same load at all times. As a result, there is no point in including cells with different capacities, different states of health, or different power outputs in the storage system.

4) The remaining usable energy of a storage unit, which in the case of the mobility application translates into the calculated remaining range of the vehicle, is determined by the Li-ion cell with the lowest charge of the electrical energy storage unit. The result is a displayed remaining range which may be significantly less than the actual energy remaining in the storage unit.

In WO2018154206A1 and WO2018193173A1, the Applicant disclosed an electrical energy storage unit comprising a distributed multilevel inverter. In this architecture, groups of electrical energy storage cells are associated with respective conversion modules. This electrical energy storage unit can supply different voltages and supports different recharging systems.

Herein, we disclose a solution to the above-mentioned drawbacks of the state of the art by providing an electrical energy storage unit formed by the association of several electrical energy storage modules and distributed power conversion means, which is suitable for direct connection to different types of electrical networks present in an electrified vehicle, such as a hybrid or all-electric vehicle, or in an electrical microgrid integrating an electrical energy storage device.

### SUMMARY

According to a first aspect, an electrical energy storage module which comprises a plurality of elementary storage cells. The module comprises at least one cell unit including a plurality of so-called elementary storage cells connected in series and integrated power-switching means dedicated to this cell unit, delivering, between two power output terminals of the cell unit, a positive DC voltage, a negative DC voltage, a zero voltage or a high impedance state, depending on a command received by the cell unit.

According to a particular feature, said dedicated integrated power-switching means comprises separate power-switching means and supervision means, the supervision means being realized in the form of an electronic supervision board implanted at an upper face of said cell unit.

According to a particular feature, the power-switching means takes the form of a power-switching electronic board comprising an “H” power-switching bridge, this power-switching electronic board being implanted at a side face of said cell unit.

According to a particular feature, the module comprises means for cooling the power-switching electronic board arranged between this power-switching electronic board and the side face of said cell unit.

According to a particular feature, the side face of the cell unit is a transverse face of this cell unit and the module comprises a transverse assembly plate disposed against this transverse face, the cooling means being sandwiched between the transverse assembly plate and the power-switching electronic board.

According to a particular feature, the transverse assembly plate and the cooling means of the power-switching electronic board form a common part. Such a common part is also referred to as a “power module”.

According to another particular feature, the transverse assembly plate and the power-switching electronic board form a common part.

According to another particular feature, the side face of the cell unit is a longitudinal face of this cell unit and the module comprises a longitudinal assembly plate arranged against this longitudinal face, the cooling means comprising a cooling plate juxtaposed in sandwich fashion between the longitudinal assembly plate and the power-switching electronic board and/or a cooling plate covering the power-switching electronic board.

According to a particular feature, the module comprises a cooling plate forming a base on which the cell unit (U1-1, U1-2; U2-1, U2-2) is placed.

According to yet another special feature, the power-switching means comprise power transistors of the “MOSFET”, “HEMT” or “SiC” type.

According to yet another special feature, the cell unit comprises six elementary storage cells of the Li-ion type.

According to yet another special feature, the electrical energy storage module comprises at least two cell units, these cell units being disconnected or connected in series by their power output terminals.

Another aspect relates to an electrical energy storage unit comprising a plurality of electrical energy storage modules as briefly described above, wherein the modules are organized into at least one set of modules, the modules of the set being aligned in at least one row, the cell units comprised in the aligned modules being connected in series by their power output terminals between first and second conductive lines associated with the set of modules and being connected to a cooling circuit, and each cell unit being independently controlled via its supervision means. According to a particular embodiment suitable for three-phase AC operation, the electrical energy storage system comprises three sets of modules as described above, with which three respective current conductor lines and a common neutral conductor line are associated.

A further aspect relates to a stationary or mobile electrical device comprising an electrical energy storage unit as described above. According to a particular embodiment, the electrical device is an electrical network or electrical microgrid integrating the production, storage and/or distribution of electrical energy.

### DESCRIPTION OF THE FIGURES

Further advantages and features of the claimed invention will become clearer from the following detailed description of several particular embodiments of the claimed invention, with reference to the appended drawings, wherein:

FIG. 1 is a simplified perspective drawing of a first embodiment of an electrical energy storage module.

FIG. 2 is a drawing showing a top view of the principle architecture of a first electrical energy storage unit created by combining a plurality of the modules shown in FIG. 1.

FIG. 3 is a schematic diagram of a cell unit included in the electrical energy storage module shown in FIG. 1.

FIG. 4 is a simplified perspective drawing of a second embodiment of an electrical energy storage module.

FIG. 5 is a drawing showing a top view of the principle architecture of a second electrical energy storage unit created by combining a plurality of the modules shown in FIG. 4.

### DETAILED DESCRIPTION

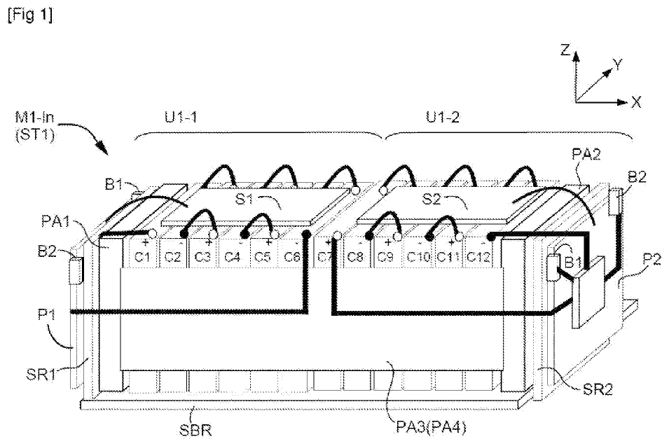

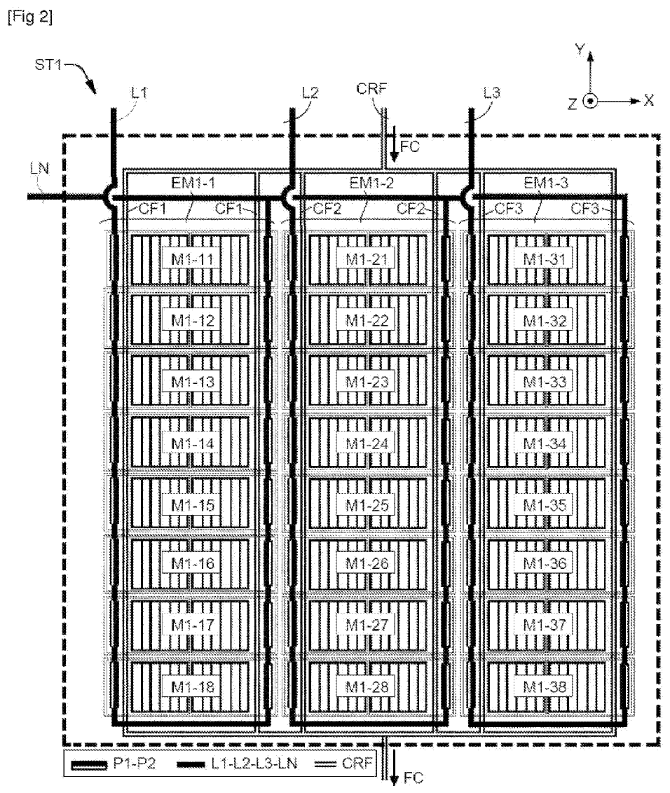

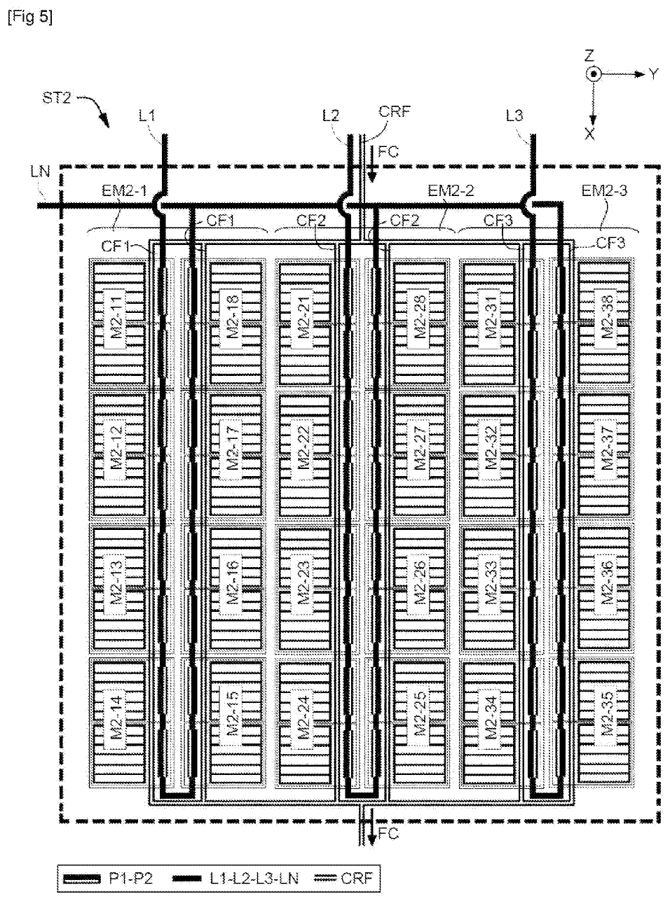

With reference to FIGS. 1 to 5, two particular embodiments ST1 and ST2 of an electrical energy storage device are described below. In general, it should be noted that the spatial frame of reference considered in the present patent application for the electrical energy storage units ST1 and ST2 is the orthogonal XYZ spatial reference frame shown in FIGS. 1 and 2 and FIGS. 4 and 5. In this orthogonal XYZ spatial reference frame, the X, Y and Z axes correspond respectively to a longitudinal horizontal axis, a transverse horizontal axis and a vertical axis. The electrical energy storage units ST1 and ST2, whose general arrangement is shown in FIGS. 2 and 5, respectively, are considered to lie on a horizontal plane XY.

In these examples, the electrical energy storage units ST1 and ST2 are of the Li-ion type and each comprise several sets of modules associated with current lines. The module sets each comprise a number of series-connected modules which are switched on or off according to the current/voltage requirements of the consumer devices. The consumer devices here are, for example, a rotating AC-powered electric traction machine or a DC power bus for an electric vehicle. In the case of powering a rotating electrical machine, each module assembly of the storage unit supplies, on the associated power line, the alternating current required to power one of the phases of the rotating electrical machine.

In the example of a power grid application, the storage unit is connected to a three-phase power grid, for example, and exchanges energy bidirectionally. The storage unit can also be connected to a string of photovoltaic panels, providing a DC voltage bus.

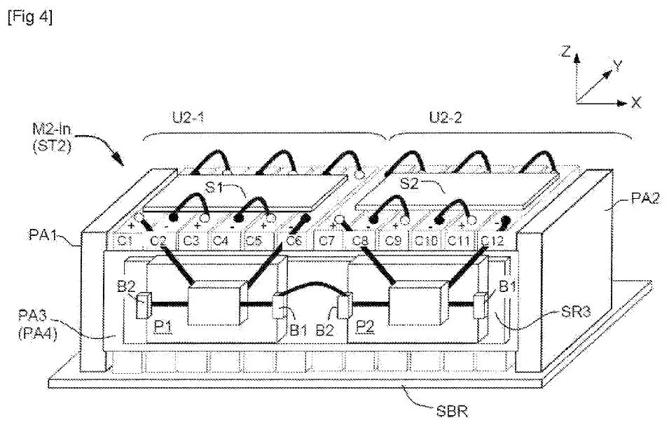

With particular reference to FIGS. 2 and 4, the electrical energy storage unit ST1 (ST2) comprises three sets of electrical energy storage cell modules EM1-1 to EM1-3 (EM2-1 to EM2-3) connected respectively to three current conductor lines L1 to L3, as well as to a common neutral conductor line LN and a cooling circuit CRF. Sets EM1-1, EM1-2 and EM1-3 (EM2-1, EM2 -2 and EM2-3) each comprise eight modules, namely, M1-11 to M1-18, M1-21 to M1-28 and M1-31 to M1-38 (M2-11 to M2-18, M2-21 to M2-28 and M2-31 to M2-38), respectively. In this way, the electrical energy storage unit ST1 (ST2) can supply a three-phase rotating electrical machine or be connected to an electrical network via the three current lines L1 to L3 and the neutral line N.

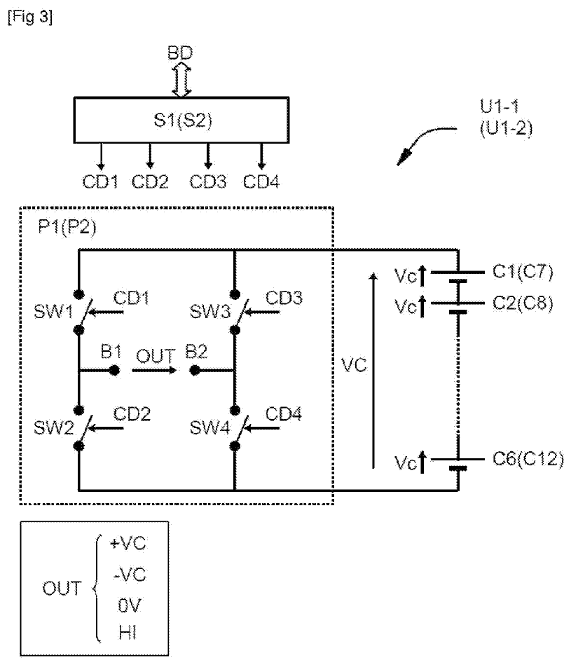

With particular reference to FIGS. 1 and 3, the general architecture of any cell module M1-In of the twenty-four modules of the electrical energy storage system ST1 is now described in detail, with I varying from 1 to 3 and n varying from 1 to 8, which respectively represent the set of modules to which the module in question belongs and an order occupied by the latter within its set of modules.

Referring to FIG. 1, in this embodiment the module M1-In comprises two cell units U1-1 and U1-2 with identical architecture. The cell unit U1-1 essentially comprises six electrical energy storage cells C1 to C6, a power-switching electronic board P1 and a supervision board S1. The cell unit U1-2 essentially comprises six electrical energy storage cells C7 to C12, a power-switching electronic board P2 and a supervision board S2.

Referring to FIG. 3, in cell unit U1-1 (U1-2), cells C1 to C6 (C7 to C12) are electrically connected in series. The electronic power-switching board P1 (P2) is an H-shaped switching bridge comprising four electronic switches SW1 to SW4, for example MOSFET, HEMT or SIC transistors. The supervision board S1 (S2) is an electronic control unit typically connected to a data communication bus BD of the electrical energy storage device ST1. Through the data communication bus BD, the supervision boards S1, S2 of all the modules are in data communication with a computer (not shown) responsible for the general supervision of the electrical energy storage device ST1 and connected to a data communication bus (not shown) of the vehicle, typically a “CAN” type bus. Supervision board S1 (S2) generates switching commands CD1 to CD4 for electronic switches SW1 to SW4 based on instructions received via data communication bus BD. The supervision board S1 (S2) also provides diagnostic and monitoring functions for each cell C1 to C6 (C7 to C12). The supervision board S1 (S2) monitors cells C1 to C6 (C7 to C12) with regard to their state of charge (“SOC”), their state of health (“SOH”), and temperature. To avoid complicating FIGS. 1 and 3, the electrical connections between the supervision board S1 (S2) and the cells C1 to C6 (C7 to C12), to obtain cell terminal voltage and incoming/outgoing current measurements, are not shown in these figures.

Depending on an instruction received by the supervision board S1 (S2), from which switching commands CD1 to CD4 are derived, the cell unit U1-1 (U1-2) provides an output OUT between output terminals B1 and B2, which is a +VC voltage, a −VC voltage, a zero voltage OV or a high-impedance state HI.

Here, the voltage VC is approximately equal to VC=6.Vc, Vc being the voltage between cell terminals, which depends essentially on the “SOC” and “SOH” states and on temperature. In this embodiment, the choice of connecting six Li-ion cells in series to form the cell unit U1-1 (U1-2) results in a voltage VC of the order of 24V as the maximum potential difference between output terminals B1 and B2. The voltage VC=approx. 24V, obtained here with a unit of six cells in series, is a good compromise for an automotive application, based on harmonic generation and cost considerations. The voltage VC=24V represents an acceptable voltage jump with respect to harmonic generation for the current waves output by the electrical energy storage unit ST1. Of course, the number of six cells per unit is treated here by way of example, and is not limiting. The number of cells per unit depends essentially on the application. In automotive applications, twelve cells per unit is also acceptable for integration in a vehicle, with a voltage VC=48V or thereabouts, which remains substantially lower than the very low DC voltage of 60V in an electric vehicle, at the cost, however, of a degradation in the quality of the current waves that can complicate the control of the rotating electric traction machine. This is also acceptable for a power grid application, with additional filtering at the storage unit output to limit voltage harmonics.

The high-impedance state HI is achieved by blocking all the MOSFET transistors of electronic switches SW1 to SW4, by controlling their gate electrodes accordingly. In the high-impedance state HI, electronic switches SW1 to SW4 are all electrically open, and output terminals B1 and B2 are electrically isolated from cells C1 to C6 (C7 to C12). By placing the cell units of the electrical energy storage unit ST1 in the high-impedance state HI, the storage system ensures that a person who has to open the storage unit for a maintenance operation is not exposed to electrical risk.

As shown in FIG. 1, the cell unit U1-1 (U1-2) is arranged spatially in a generally parallelepipedal volume. The cells C1 to C6 (C7 to C12) forming the cell unit U1-1 (U1-2) are typically of the “prismatic” type here, with the general external shape of a flat parallelepiped. Thus, cells C1 to C6 (C7 to C12) have two parallel faces aligned in the YZ plane, two parallel edges aligned in the XY plane and two further parallel edges aligned in the XZ plane. Cells C1 to C6 (C7 to C12) are juxtaposed against one another by respective faces and form a stack along the X axis.

In the module M1-In, as shown in FIG. 1, cell units U1-1 and U1-2 are juxtaposed against one another by first end faces which are those of cells C6 and C7. The module M1-In thus comprises a stack of twelve cells C1 to C12 along the X axis. The cells C1 to C12 are placed on an base plate SBR in the XY plane, which has a support and cooling function. Cells C1 to C12 are held tightly together by mechanical joining means PA1, PA2, PA3 and PA4 in the form, for example, of transverse joining plates PA1, PA2 and longitudinal joining plates PA3, PA4. Transverse joining plates PA1 and PA2 extend in planes YZ and are arranged against second end faces of cell units U1-1 and U1-2, which are those of cells C1 and C12. Longitudinal assembly plates PA3 and PA4, of which only PA3 is visible in FIG. 1, extend in planes XZ and support clamping means (not shown) which, when clamped, bring transverse assembly plates PA1, PA2 together along the X axis. Cells C1 to C12 are thus sandwiched and held stationary between transverse assembly plates PA1, PA2. The outer shell of the prismatic cells is very strong and adapted to withstand clamping pressure.

For cell unit U1-1, the power-switching electronic board P1 is mounted at its second end face, corresponding to cell C1, in a YZ plane. A cooling plate SR1 is sandwiched between the transverse assembly plate PA1 and the power-switching electronic board P1. The electronic supervision board S1 is mounted on the top of the cell unit U1-1, close to the cell connection terminals C1 to C6.

For the cell unit U1-2, similarly to the cell unit U1-1, the power-switching electronic board P2 is mounted at its second end face, corresponding to the C12 cell, in a YZ plane. A cooling plate SR2 is sandwiched between the transverse assembly plate PA2 and the power-switching electronic board P2. The electronic supervision board S2 is mounted on the top of the cell unit U1-2, close to the connection terminals for cells C7 to C12.

Cooling of the module M1-In is achieved here by means of the above-mentioned plates SBR, SR1 and SR2. These plates are typically made of aluminum or copper, to ensure satisfactory heat conduction, and can be configured to suit the application. In this way, they can be solidly structured to conduct heat to a cold source and/or include a liquid-coolant cooling circuit. For example, the cold source could be formed by the SBR cooling plate integrating a liquid coolant circuit, with the cooling plates SR1 and SR2 then being solid and conveying the heat to the plate SBR. Of course, in other embodiments, the cold source can also be formed by the cooling plate SR1 and/or SR2.

In one variant, the plates SR1 and SR2 can be omitted, and their cooling functions will then be performed by the transverse assembly plates PA1, PA2. In other words, in this variant, the transverse assembly plate PA1 (PA2) and the cooling means SR1 (SR2) of the power-switching electronic board P1 (P2) form a common part. These plates PA1, PA2 will then be modified to provide good thermal coupling with the plate SBR as a cold source.

In an embodiment with immersive cooling in a dielectric fluid, the module M1-In will typically comprise at least one cooling plate with fins, or with any other geometry designed to promote heat exchange. The position and geometry of the cooling plate will then be chosen to promote the flow of the dielectric fluid, whether static, in conducted flow or delivered locally, for example, in spray or drip form.

In another embodiment, the power-switching electronic board P1 (P2) may take the form of a power module. In other words, in this variant, the transverse assembly plate PA1 (PA2) and the power-switching electronic board P1 (P2) form a common part. As the outer shell of a power module is usually very strong mechanically, the power module P1 (P2) can perform the function of the transverse assembly plate PA1 (PA2), thus eliminating the need for the latter.

Referring again to FIG. 2, the general arrangement of modules M1-11 to M1-18, M1-21 to M1-28 and M1-31 to M1-38 of the storage unit ST1 in their respective module assemblies EM1-1, EM1-2 and EM1-3, and the connection of their cell units U1-1, U1-2, to current lines L1 to L3, neutral line LN and cooling circuit CRF is now described.

In the module assembly EM1-1 (EM1-2 or EM1-3), the eight modules M1-11 to M1-18 (M1-21 to M1-28 or M1-31 to M1-38) are juxtaposed in a single row with their long side faces parallel to the XZ plane, aligned along the Y axis. Electrical connection conductors and cooling lines for connecting the modules are arranged on either side of the row of modules. Units U1-1 and U1-2 of modules M1-11 to M1-18 (M1-21 to M1-28 or M1-31 to M1-38) are electrically connected in series between current line L1 (L2 or L3) and neutral line LN. Thus, the units U1-1 aligned on a first side of the row are connected in series by the output terminals B1, B2, of their power-switching boards P1, which are located on first small side faces parallel to the YZ plane (see FIG. 1) of the modules M1-11 to M1-18 (M1-21 to M1-28 or M1-31 to M1-38). The units U1-2 aligned on a second side of the row are likewise connected in series via the output terminals B1, B2 of their power-switching boards P2, which are located on the second small side faces parallel to the YZ plane (see FIG. 1) of the modules M1-11 to M1-18 (M1-21 to M1-28 or M1-31 to M1-38). The units U1-1 and U1-2 of the first module M1-11 (M1-21 or M1-31) in the row are connected via the output terminals B1, B2 of their power-switching boards P1 and P2 to the current line L1 (L2 or L3) and the neutral line LN, respectively. The units U1-1 and U1-2 of the last module M1-18 (M1-28 or M1-38) in the row are connected in series via output terminals B1, B2 of their power-switching boards P1 and P2.

By virtue of its architecture, it is clear to the person skilled in the art that the electrical energy storage unit disclosed herein allows the generation of any type of waveform, in particular a sine wave, on each of its current lines, due to the individual control of the cell units. In addition, the ability to control individual cell units enables the implementation of a dynamic cell balancing strategy.

For the cooling circuit CRF, cooling lines CF1 (CF2 or CF3), in which a heat transfer fluid FC flows, are located on either side of the row of modules M1-11 to M1-18 (M1-21 to M1-28 or M1-31 to M1-38). The cooling means of modules M1-11 to M1-18 (M1-21 to M1-28 or M1-31 to M1-38), such as the above-mentioned plates SBR, SR1 and SR2 (see FIG. 1), are connected to cooling lines CF1 (CF2 or CF3) for the flow of heat transfer fluid FC, which evacuates the heat to a heat exchanger (not shown).

With particular reference now to FIGS. 4 and 5, the general architecture of any cell module M2-In among the twenty-four modules of the electrical energy storage unit ST2 is described below, with, as for the module M1-In described above, I varying from 1 to 3 and n varying from 1 to 8, which respectively represent the set of modules to which the module in question belongs and the order occupied by it in its set of modules.

As can be seen in FIG. 4, the module M2-In differs from the module M1-In essentially in the spatial arrangement of the power-switching boards P1 and P2 in the respective cell units U2-1 and U2-2 of the module M2-In, as well as in the arrangement of the cooling means.

The power-switching boards P1 and P2 are mounted on the longitudinal assembly plate PA3 located at a first major longitudinal face, parallel to the XZ plane, of the module M2-In. The power-switching boards P1 and P2 are placed opposite cells C1 to C6 and C7 to C12 of units U2-1 and U2-2, respectively. A cooling plate SR3, against which the power-switching boards P1 and P2 are seated, is inserted between them and the longitudinal assembly plate PA3. The cooling plate SR3 is used here to cool the two power-switching boards P1, P2. Alternatively, the cooling plate SR3 is not inserted between the longitudinal assembly plate PA3 and the boards P1, P2, but covers the boards P1, P2. Alternatively, two cooling plates can be provided on either side of the power-switching boards P1, P2.

Unlike the module M1-In, wherein the boards P1, P2 of the units U1-1, U1-2 are electrically disconnected at their output terminals B1, B2 inside the module, the boards P1, P2 of the module M2-In are electrically pre-connected in series by a conductor LS between their output terminals B1, B2, for example, by soldering or screwing.

In this embodiment, the integration of the power-switching boards P1, P2 in the module M2-In, as described above, minimizes the length of the line conductors, thus reducing the inductances that cause overvoltages. This makes it possible to reduce the capacity of the filtering and decoupling capacitors installed on boards P1 and P2, designed to limit these overvoltages.

With reference to FIG. 5, the general arrangement of modules M2-11 to M2-18, M2-21 to M2-28 and M2-31 to M2-38 of the storage unit ST2 in their respective module assemblies EM2-1, EM2-2 and EM2-3, and the connection of their cell units U2-1, U2-2, to current lines L1 to L3, neutral line LN and cooling circuit CRF, is now described.

In the module assembly EM2-1 (EM2-2 or EM2-3), the eight modules M2-11 to M2-14 and M2-15 to M2-18 (M2-21 to M2-24 and M2-25 to M2-28 or M2-31 to M2-34 and M2-35 to M2-38) are juxtaposed respectively in first and second parallel rows by their small side faces parallel to the XZ plane, being aligned along the X axis. The modules in each of the two rows are arranged so that their large longitudinal sides bearing the power-switching boards P1 and P2 (see FIG. 4) face one another. In this way, modules M2-11, M2-12, M2-13 and M2-14 (M2-21, M2-22, M2-23 and M2-24 or M2-31, M2-32, M2-33 and M2-34) respectively face modules M2-18, M2-17, M2-16 and M2-15 (M2-28, M2-27, M2-26 and M2-25 or M2-38, M2-37, M2-36 and M2-35) with their large longitudinal sides carrying the power-switching boards P1, P2. Electrical connection conductors and cooling lines for connecting the modules are arranged in an interspace between the two rows of modules. Modules M2-11 to M2-18 (M2-21 to M2-28 or M2-31 to M2-38) are electrically connected in series via terminals B1, B2 between current line L1 (L2 or L3) and neutral line LN, with units U2-1 and U2-2 of each module pre-connected in series as described above. The first modules M2-11 (M2-21 or M2-31) and M2-18 (M2-28 or M2-38) in the first and second rows are connected to current line L1 (L2 or L3) and neutral line LN, respectively. The last modules M2-14 (M2-24 or M2-34) and M2-15 (M2-25 or M2-35) in the first and second rows are connected together to complete the series connection of all cell units U2-1, U2-2 in the assembly EM2-1 (EM2-2 or EM2-3).

For the cooling circuit CRF, a cooling line CF1 (CF2 or CF3), through which a heat transfer fluid FC flows, is located between the two rows of modules M2-11 to M2-18 (M2-21 to M2-28 or M2-31 to M2-38). The cooling means, such as the plates SBR and SR3 (see FIG. 4), of modules M2-11 to M2-18 (M2-21 to M2-28 or M2-31 to M2-38) are connected to this cooling line CF1 (CF2 or CF3) for the circulation of the heat transfer fluid FC, which evacuates the calories to a heat exchanger (not shown).

In FIG. 5, the cooling line CF1 (CF2 or CF3) is shown in the form of two branches for ease of representation. Of course, the central arrangement of the electrical and cooling connections between the two rows of modules is an advantage of this embodiment, promoting a reduction in length and increased compactness.

Generally speaking, in addition to the advantages already mentioned above, the disclosed storage system enables units with different capacities, different power ratings, different electrochemical compositions and even different states of health to be mixed in the same storage unit. In a storage unit, fault tolerance can be easily increased by integrating additional cell units. Furthermore, a degraded cell does not affect the performance of the entire storage unit, which is good for the vehicle's electric range. With the architecture of the storage system proposed herein, a vehicle supervisor can easily calculate the vehicle's electric range from a sum of the remaining capacities in the cells of the storage unit.

In addition, the architecture of the storage system is such as to facilitate high-power AC recharging, compared with solutions in the state of the art. The storage unit enables a three-phase socket to be provided on-board a vehicle, which is of particular benefit, for example, in a commercial vehicle or for high-power three-phase recharging of another vehicle in “V2V” technology.

Calculations have revealed a significant economic advantage provided by the architecture of the disclosed storage system compared with solutions in the state of the art, particularly in terms of manufacturing costs and vehicle repair/maintenance costs. Moreover, the modular design of the storage system is perfectly suited to a high-volume, high-output industry such as the automotive industry.

The storage system is not limited to the particular embodiments described here by way of example. Depending on the application, the skilled person will be able to make various modifications and variants falling within the scope of protection of the claimed invention.

1. An electrical energy storage module comprising a plurality of elementary storage cells wherein the electrical energy storage module comprises at least one cell unit including a plurality of said elementary storage cells connected in series and dedicated integrated power-switching means to this cell unit delivering, between two power output terminals of said cell unit, a positive DC voltage (+VC), a negative DC voltage (−VC), a zero voltage or a high impedance state, according to a command received by said cell unit.

2. The electrical energy storage module according to claim 1, wherein said dedicated integrated power-switching means comprise separate power-switching means and supervision means, the supervision means being implemented in the form of an electronic supervision board located at an upper face of said cell unit.

3. The electrical energy storage module according to claim 2, wherein the power-switching means are in the form of a power-switching electronic board comprising an H-shaped power-switching bridge said power-switching electronic board being installed at a side face of said cell unit.

4. The electrical energy storage module according to claim 3, it wherein the electrical energy storage module comprises means for cooling the power-switching electronic board arranged between this power-switching electronic board and the side face of said cell unit.

5. The electrical energy storage module according to claim 4, wherein the side face of the cell unit is a transverse face of this cell unit and in that the module comprises a transverse assembly plate arranged against this transverse face, the cooling means being juxtaposed in sandwich fashion between the transverse assembly plate and the electronic power-switching board.

6. The electrical energy storage module according to claim 5, wherein the transverse assembly plate and the cooling means of the power-switching electronic board form a common part.

7. The electrical energy storage module according to claim 5, wherein the transverse assembly plate and the power-switching electronic board form a common part.

8. The electrical energy storage module according to claim 3, wherein the side face of the cell unit is a longitudinal face of this cell unit and the electrical energy storage module comprises a longitudinal assembly plate arranged against this longitudinal face, the cooling means comprising a cooling plate juxtaposed in sandwich fashion between the longitudinal assembly plate and the power-switching electronic board and/or a cooling plate covering the power-switching electronic board.

9. The electrical energy storage module according to claim 1, wherein said electrical energy storage module comprises a cooling plate forming a base on which the cell unit is placed.

10. The electrical energy storage module according to claim 1, wherein said electrical energy storage module comprises at least two said cell unit, said cell units being disconnected or connected in series by their said power output terminals.

11. An electrical energy storage unit comprising a plurality of electrical energy storage modules according to claim 1, wherein said electrical energy storage modules to are organized into at least one set of modules, said electrical energy storage modules of the set being aligned in at least one row, the cell units comprised in said aligned electrical energy storage modules being connected in series by their power output terminals between first and second conductive lines associated with said set of electrical energy storage modules and being connected to a cooling circuit, and each cell unit being independently controlled via its said supervision means.

12. The electrical energy storage unit according to claim 11, suitable for three-phase AC operation, wherein said electrical energy storage unit comprises three of said module assemblies with which three respective current conductor lines and a common neutral conductor line are associated.

13. A stationary or mobile electrical device, comprising an electrical energy storage unit according to claim 11 or 12.

14. The electrical device according to claim 13, wherein the electrical device is designed as an electrical network or electrical microgrid integrating the production, storage and/or distribution of electrical energy.

15. The electrical device according to claim 13, wherein the electrical device is designed as an electrified vehicle.
